(19) United States
(12) Patent Application Publication
(10) Pub. No.: US 2026/0114205 A1
(43) Pub. Date: Apr. 23, 2026

(54) METHOD FOR TRANSFERRING A SEMICONDUCTOR LAYER

(71) Applicant: COMMISSARIAT A L’ENERGIE ATOMIQUE ET AUX ENERGIES ALTERNATIVES, PARIS (FR)

(72) Inventors: Shay REBOH, GRENOBLE CEDEX 09 (FR); Frédéric MAZEN, GRENOBLE CEDEX 09 (FR); Jean-Michel HARTMANN, GRENOBLE CEDEX 09 (FR)

(21) Appl. No.: 19/143,254

(22) PCT Filed: Dec. 22, 2023
(86) PCT No.: PCT/EP2023/087625

§ 371 Date: Jun. 25, 2025

(30) Foreign Application Priority Data
Dec. 27, 2022 (FR) FR2214544

(51) Int. Cl. H10P 54/30; H10P 10/00; H10P 30/28; H10P 90/00

(52) U.S. Cl. CPC H10P 54/30; H10P 10/128; H10P 30/28; H10P 90/1904

(57) ABSTRACT

A method for transferring a semiconductor layer from a donor substrate to a receiver substrate includes first implantation of first light ions into the donor substrate at a predetermined implantation depth to form a buried fragile plane, epitaxy on the donor substrate of the semiconductor layer, second implantation of second light ions into the donor substrate through the semiconductor layer to be transferred level with the fragile plane, assembly by bonding of the receiver substrate and of the donor substrate covered with the semiconductor layer to be transferred, the semiconductor layer to be transferred being placed between the receiver substrate and donor substrate, and fracturing by annealing the donor substrate along the buried fragile plane, the first ions implanted with a first dose so that there is no fracturing at the predetermined implantation depth, and the second ions implanted with a second dose such that the donor substrate fractures.

### TECHNICAL FIELD OF THE INVENTION

The technical field of the invention is that of methods for transferring semiconductor layers.

The present invention more particularly relates to a method for transferring a semiconductor layer by ion implantation, assembly and fracturing wherein the semiconductor layer has reduced defects prior to the assembly step.

### TECHNOLOGICAL BACKGROUND OF THE INVENTION

To increase the integration density of integrated circuits, a new technique called 3D monolithic integration consists in stacking layers of electronic devices on top of each other.

Electronic devices are typically transistors. Each layer or level of transistors is formed in a semiconductor layer called the active layer. The first level of transistors is formed on the surface of an initial substrate, also called a wafer. The second level of transistors is manufactured from a semiconductor layer formed on the first level of transistors, stated differently above the surface of the initial substrate.

To obtain such a semiconductor layer, it is possible to transfer, onto the initial so-called receiver substrate, a semiconductor layer from another so-called donor substrate. A known transfer technique called Smart Cut™ is based on the combination of light ion implantation into the donor substrate, molecular adhesion assembly of the donor and receiver substrates and fracturing annealing of the donor substrate.

The method comprises 1) providing a donor substrate, generally a silicon wafer, 2) implanting ions, typically light ions such as hydrogen, through the surface of the donor substrate to create nano-cavities buried inside the donor substrate, to a depth determined by the implantation depth, and delimit the semiconductor layer to be transferred, 3) assembling the donor substrate to a receiver substrate, and then 4) finally annealing (heating) the assembly which activates formation of dihydrogen (H₂). This gas supplies the nano-cavities and makes them grow. Due to the mechanical stress created by the interface between the donor and receiver substrates assembled, the nano-cavities expand and laterally gather at the depth determined by the implantation, creating micro-cracks and a final fracture that rapidly extends throughout the wafer. Separation of the semiconductor layer from the donor substrate and its transfer to the receiver substrate is then performed.

This method provides many advantages and is well mastered. However, some problems remain, including one in particular inherent in the step of implanting light ions. Indeed, implantation of light ions induces defects in the semiconductor layer that alter its electrical performance, and therefore its quality. These defects are related to the fact that ions induce defects of different kinds (vacancies, interstitial defects, hydrogen complexes, nano-cavities) not only about the determined implantation depth, but also along their path in the donor substrate. Thus, defects are present in the semiconductor layer, due to implantation of light ions, with a density proportional to the dose at which implantation is carried out. They affect the mobility of the charge carriers, and therefore the electrical characteristics of the semiconductor layer. It should be noted that heating that takes place during fracturing annealing does not effectively heal defects formed by implantation and may even lead to the growth/formation of new defects or cavities.

It is essential to reduce this number of defects in the semiconductor layer in order to guarantee satisfactory electrical performance for the electronic components manufactured therein, by maintaining an implantation dose adapted to the transfer of said semiconductor layer.

For this, a conventionally used solution consists in reducing the number of defects after the transfer step, by subjecting the receiver substrate (which comprises the semiconductor layer transferred) to high temperatures, that is, temperatures greater than 900° C. or 1000° C., applied for long times, for example several hours. But, such temperatures should be avoided when the semiconductor layer has been transferred onto a receiver substrate comprising a layer of electronic devices previously formed. Indeed, they degrade the performance, especially the electrical performance, of the electronic devices of this underlying layer. It is therefore impossible to reduce the defects created by implantation of light ions in this way.

In the context of a method for transferring a semiconductor layer based on light ion implantation, there is therefore a need to reduce the number of defects in the semiconductor layer other than by annealing carried out at high temperature after fracturing.

### SUMMARY OF THE INVENTION

The invention provides a solution to the problems discussed previously, by providing the single implantation step to be replaced by two implantation steps and by performing a step of epitaxially growing the semiconductor layer between the two implantation steps. Additionally, the implantation conditions of each of the implantation steps, especially the ions implanted and the implantation dose(s) selected, are adapted as a function of epitaxy and fracturing annealing to induce fracturing only during fracturing annealing.

One aspect of the invention thus relates to a method for transferring a semiconductor layer from a donor substrate to a receiver substrate, the method comprising the following successive steps of:
firstly implanting first light ions into the donor substrate at a predetermined implantation depth so as to form a buried brittle plane at the predetermined implantation depth,
epitaxially growing, on the donor substrate, the semiconductor layer to be transferred,
secondly implanting second light ions into the donor substrate through the semiconductor layer to be transferred at the brittle plane,
assembling by bonding the receiver substrate and the donor substrate covered with the semiconductor layer to be transferred, the semiconductor layer to be transferred being disposed between the receiver and donor substrates, and
fracturing by annealing, referred to as fracturing annealing, the donor substrate in the buried brittle plane,
   in which method:
the first ions are selected and implanted at a first dose so that, during epitaxy, there is no fracturing at the predetermined implantation depth,
the second ions are selected and implanted at a second dose so that, during fracturing annealing, fracturing of the donor substrate takes place.

Thus, implantation of the first light ions, that is, ions the atomic weight of which is less than or equal to 11, is carried out with a dose such that the first ions do not induce fracturing at the predetermined implantation depth when epitaxially growing the semiconductor layer to be transferred.

Under these conditions, the thermal budget (defined by the temperature and duration of application of this temperature) used during the epitaxy step does not result in the growth and gathering of the nano-cavities of the buried brittle plane, that is, the nano-cavities formed at the implantation depth predetermined by the first implantation. There are several reasons for this, including the fact that the density of nano-cavities and/or the amount of gas produced is insufficient.

It should be noted that if a single implantation were carried out before epitaxy, then the ions implanted would necessarily be selected so that, at the implanted dose, there would be fracturing after assembling the donor and receiver substrates. The dose implanted would therefore be sufficiently high for the heat treatment inherent in epitaxy to lead to fracturing of the donor substrate. To avoid this, the epitaxy temperature would have to be limited to 400° C. maximum. But, it is not currently possible to form a semiconductor layer at such a temperature.

The first implantation therefore enables epitaxy to be carried out without fracturing the donor substrate or creating defects in the semiconductor layer.

Additionally, epitaxially growing the semiconductor layer is followed by the second implantation. This second implantation is carried out at substantially the same depth as the first implantation (taking account of the epitaxial thickness) so that, during fracturing annealing, fracturing of the donor substrate is obtained due to the accumulation of ions implanted during the first and second implantations. The implantation depth is mainly a function of the ion implantation energy. Software (such as SRIM for “Stopping and Range of Ions in Matter”) can be used to simulate the required implantation energies. Both implantations take place substantially in the same plane. A difference of a few nanometres is possible, as the implanted ions may reach the nano-cavities of the brittle plane during fracturing annealing.

The semiconductor layer formed thus advantageously has only the ions implanted during the second implantation passing therethrough, in a much smaller amount than the light ions required when a single implantation is conventionally carried out.

The number of defects in the semiconductor layer is thus reduced before transfer and without the need for a high-temperature annealing step.

According to a first alternative embodiment, the method comprises, between the first implantation of light ions and the step of epitaxially growing the semiconductor layer to be transferred, an additional surface preparation step comprising the following successive sub-steps of:
deoxidising a free surface of the donor substrate,
annealing the donor substrate in an atmosphere comprising hydrogen at a temperature greater than or equal to 400° C. (and advantageously greater than or equal to 500° C.) for a duration of between 5 seconds and 10 minutes.

The higher the thermal budget of this annealing including hydrogen, referred to as H2 annealing, the lower the residual contamination of oxygen atoms at the interface between the substrate and the semiconductor layer epitaxially grown, and the better the quality of the semiconductor layer transferred. The impact of H2 annealing conditions on the quality of films deposited can be better understood by referring to Hartmann et al, “A benchmark of 300 mm RP-CVD chambers for the low temperature epitaxy of Si and SiGe”, ECS Transactions, 86 (7) 219-231 (2018).

Thus, the surface of the donor substrate is prepared for epitaxially growing the semiconductor layer to be transferred. This contributes to forming a semiconductor layer with a reduced number of defects.

According to a second alternative embodiment, the method comprises the additional steps of:
before the first implantation, a step of depositing a sacrificial layer onto a free surface of the donor substrate,
after the first implantation and before the step of epitaxially growing the semiconductor layer to be transferred, a step of removing the sacrificial layer.

The combination of deposition and removal of the sacrificial layer aims at preparing the surface for epitaxially growing the semiconductor layer to be transferred.

According to a first development of this second alternative embodiment, the sacrificial layer is a dielectric layer.

The dielectric layer is, for example, a layer of silicon oxide. It acts as a protective layer preserving the surface of the donor substrate from contamination or impurities. As it is on this surface that the epitaxy is carried out, the semiconductor layer to be transferred will be formed under better conditions, and its quality will be improved.

According to a second development of this second alternative embodiment, the sacrificial layer comprises a stack of a first sub-layer of silicon/germanium alloy, referred to as the first etch stop layer, and a second sub-layer of dielectric material disposed onto the first sub-layer, and the step of removing the sacrificial layer comprises removing the second dielectric sub-layer selectively relative to the first etch stop layer and then removing the first etch stop layer.

Like the dielectric layer, the first etch stop layer preserves the surface on which the epitaxy will be carried out, from impurities likely to degrade the semiconductor layer.

Removing the first etch stop layer makes it possible to improve surface preparation by obtaining lower surface roughness.

According to one alternative embodiment of the second preceding development, the step of epitaxially growing the semiconductor layer to be transferred is carried out at least 30 minutes after the step of removing the first stop layer.

Preferably, the step of epitaxially growing the semiconductor layer to be transferred is carried out at least 10 minutes after the step of removing the first stop layer.

This short time makes it possible to limit the risk of contamination of the surface on which epitaxially growing the semiconductor layer to be transferred will be carried out.

According to another alternative embodiment of the second development, the step of removing the first etch stop layer and the step of epitaxially growing the semiconductor layer to be transferred are carried out in a same equipment.

Thus, the risk of surface contamination is reduced and the method is simplified.

Advantageously, the method comprises, after the step of removing the first etch stop layer and before the step of epitaxially growing the semiconductor layer to be transferred, an additional step of annealing the donor substrate carried out in the same equipment as the step of removing the first stop layer and the step of epitaxially growing the semiconductor layer to be transferred.

This step of annealing the donor substrate performed in situ in the epitaxy equipment completes the step of removing the first etch stop layer and improves the quality of the surface on which the semiconductor layer to be transferred will be formed.

Advantageously, the additional step of annealing the donor substrate is carried out under the following temperature, pressure and duration conditions: 500° C., 2666 Pa (or 20 Torr), 2 minutes.

With such a thermal budget, the properties of the layer (or brittle plane) damaged by the first implantation are still compatible with a layer transfer after the second implantation.

Further to the characteristics just discussed in the preceding paragraphs, the method according to one aspect of the invention may have one or more complementary characteristics from among the following, compatible with all the preceding alternative embodiments and considered individually or according to any technically possible combination.

The first light ions are helium ions, hydrogen ions, boron ions, a mixture of helium ions and hydrogen ions or a mixture of hydrogen ions and boron ions.

The second light ions are helium ions, hydrogen ions or a mixture of helium ions and hydrogen ions.

It should be noted that it is especially advantageous to use hydrogen ions for the second implantation, rather than helium ions, as these induce fewer defects, even if the implantation dose is higher.

The semiconductor layer to be transferred is a layer of silicon (or Si), germanium (or Ge), a silicon/germanium (or SiGe) alloy, a silicon/germanium/carbon (or SiGeC) alloy, a germanium/tin (or GeSn) alloy or a silicon/germanium/tin (SiGeSn) alloy, or a stack of a sub-layer of silicon and a sub-layer of a silicon/germanium (Si/SiGe) alloy.

Alternatively, the semiconductor layer to be transferred comprises a first so-called active sub-layer of silicon (or Si), germanium (or Ge), a silicon/germanium (or SiGe) alloy, a silicon/germanium/carbon (SiGeC) alloy, a germanium/tin (GeSn) alloy or a silicon/germanium/tin (SiGeSn) alloy, and a second so-called etch stop sub-layer, such as an etch stop sub-layer of silicon/germanium alloy, disposed under the first active sub-layer, and the receiver substrate has, after the fracturing step, a residual layer originating from the donor substrate, the method then comprising the following successive steps of:
Removing the residual layer originating from the donor substrate by selectively etching said residual layer relative to the second etch stop sub-layer,
Removing the second etch stop sub-layer.

By virtue of the etch stop sub-layer and the step of selectively etching the residual layer after transfer, no chemical mechanical polishing is required to remove the residual layer originating from the donor substrate. In addition, the surface roughness of the layer transferred is reduced and its thickness controlled to achieve thinner thicknesses. The quality of the layer transferred is thus further improved.

The invention and its different applications will be better understood upon reading the following description and examining the accompanying figures.

### BRIEF DESCRIPTION OF THE FIGURES

The figures are set forth by way of indicating and in no way limiting purposes of the invention.

FIGS. 1A to 1G schematically represent steps of the method of the invention,

FIG. 2 represents several alternative embodiments of the epitaxy step of the transfer method of FIGS. 1A to 1G,

FIG. 3 sets forth the final multi-layer structure obtained with the transfer method of FIGS. 1A to 1G,

FIGS. 4A to 4K schematically represent a first particular embodiment of the method of FIGS. 1A to 1G, which makes it possible to improve the quality of the semiconductor layer,

FIGS. 5A to 5M schematically represent a second particular embodiment of the method of FIGS. 1A to 1G, which also makes it possible to improve the quality of the semiconductor layer,

FIG. 6 schematically represents a first test substrate for determining the first implantation dose,

FIG. 7 is a block diagram representing the sequence of steps for determining the first maximum dose of the first implantation step of FIG. 1B,

FIG. 8 schematically represents a second test substrate for determining the second implantation dose,

FIG. 9 is a block diagram representing the sequence of steps for determining the second minimum dose for the second implantation step of FIG. 1D,

FIG. 10 represents the density of defects generated in a silicon substrate by implanting hydrogen ions, and by implanting a mixture of helium and hydrogen ions,

FIG. 11 represents the etching rate of a layer of SiGe, as a function of the partial etching pressure and as a function of the percentage of Ge in the SiGe alloy,

FIG. 12 is a block diagram representing the sequence of steps for implementing an additional surface preparation step, this step being between the second step and the third step of the method represented in FIGS. 1A to 1G.

Unless otherwise specified, a same element appearing in different figures has a single reference.

### DETAILED DESCRIPTION

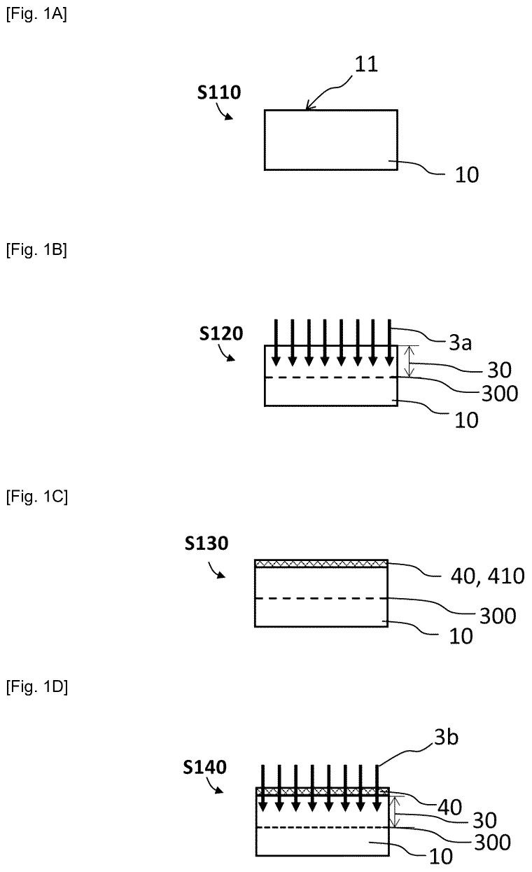

FIGS. 1A to 1G represent a schematic cross section view of steps S110 to S160 of a method for transferring a semiconductor layer 40 from a donor substrate 10 to a receiver substrate 20, which makes it possible to obtain a semiconductor layer 40 having reduced defects.

By “defects”, it is meant nano-cavities, vacancies, interstitial defects, hydrogen complexes, bubbles, exfoliations present in the semiconductor layer or on its surface, and degrading its electrical performance.

This transfer method comprises, like the Smart Cut™ method of prior art, implanting light ions, assembling two substrates by bonding and fracturing annealing.

The transfer method of the invention is remarkable in that it comprises, prior to the actual transfer carried out by the bonding step S150 and the fracturing step S160 (FIG. 1E and FIG. 1F), two steps S120 and S140 of implanting light ions (FIG. 1B and FIG. 1D) and an epitaxy step S130 (FIG. 1C) interposed between these two implantation steps S120 and S140.

With reference to FIG. 1A, the transfer method starts at the first step S110 with providing a donor substrate 10. The donor substrate 10 refers to a support substrate, preferably a semiconductor substrate, for example of silicon. Generally speaking, a “substrate” refers a wafer or slice.

The donor substrate 10 has an upperface 11, referred to as the free surface, which is substantially planar.

With reference to FIG. 1B, the first step S110 is followed by a step S120 of implanting first light ions 3a into the donor substrate 10, through the free surface 11, to a predetermined depth 30, referred to as the implantation depth. This first implantation S120 creates defects in the donor substrate 10 in a so-called brittle plane 300 located at the implantation depth 30. The plane 300 is said to be brittle because the defects created embrittle the donor substrate 10.

The implantation depth 30 is, for example, between 100 nm and 1000 nm. It is measured from the free surface 11 and perpendicularly to the same surface. For example, implantation S120 of the first ions is carried out at an energy such that the maximum of the profile of the ions implanted is at about 300 nm depth.

This implantation energy depends on the ion species selected. If the first species implanted is helium, it is in the order of 35 keV to obtain an implantation depth of 300 nm.

Light ions are species defined by an atomic weight less than or equal to 11. The first ions 3a are preferably selected from hydrogen (or H), helium (or He), boron (or B), a mixture of helium and hydrogen (or “He+H”) or a mixture of hydrogen and boron (or “H+B”). These species are indeed known to create a buried brittle plane likely to lead to Smart Cut™ transfer.

In the Smart Cut™ method, the step of implanting the light ions is conventionally associated with an annealing step performed at an annealing temperature generally of between 350° C. and 600° C. to fracture the donor substrate and transfer the semiconductor layer.

In the method according to the invention, the step S120 of implanting the first ions 3a is not followed by a “conventional” annealing step, but is followed by an epitaxy step S130, illustrated in FIG. 1C, to form the semiconductor layer 40.

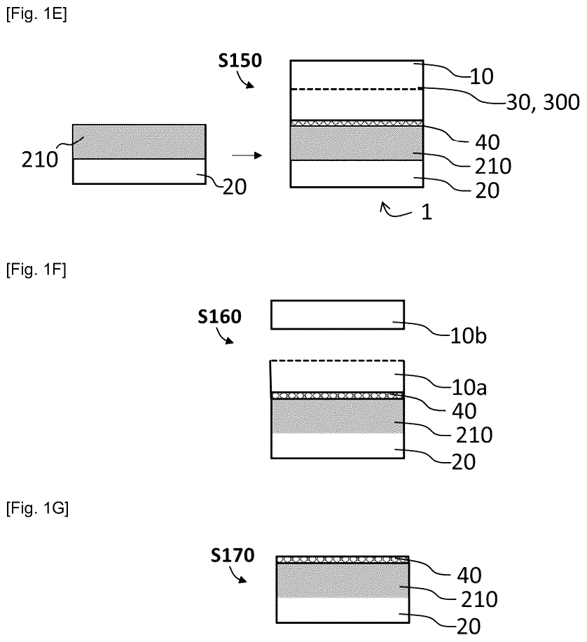

FIG. 2 sets forth several alternative embodiments for performing this epitaxy step S130.

At the end of this step S130, the semiconductor layer 40 may be a semiconductor layer 410, preferably thin, that is, with a thickness of between 5 nm and 30 nm, and formed from one of the following materials: silicon (or Si), germanium (or Ge), a silicon/germanium (or SiGe) alloy, a silicon/germanium/carbon (or SiGeC) alloy, a germanium/tin (or GeSn) alloy or a silicon/germanium/tin (SiGeSn) alloy.

The semiconductor layer 40 can alternatively be a stack of semiconductor sub-layers, for example a stack of a sub-layer of silicon and a sub-layer of silicon/germanium (Si/SiGe) alloy or, preferably, a stack of a first so-called active sub-layer 430 and a second so-called etch stop sub-layer 420, such as an etch stop sub-layer of a silicon/germanium (SiGe) alloy. The etch stop sub-layer 420 is disposed under the active sub-layer 430.

The active sub-layer 430 is then similar to the semiconductor layer 410, that is, it is formed from one of the following materials: silicon (or Si), silicon/germanium (or SiGe) alloy, silicon/germanium/carbon (SiGeC) alloy, germanium/tin (or GeSn) alloy or silicon/germanium/tin (SiGeSn) alloy and its thickness is between 2 nm and 30 nm. The etch stop sub-layer 420 is preferably of an SiGe alloy with a germanium concentration of between 20% and 50%. The etch stop sub-layer 420 may additionally have a thickness of between 5 nm and 150 nm.

More generally, the stack of semiconductor sub-layers may comprise several active sub-layers and etch stop sub-layers disposed alternately (not represented in FIG. 2). The thickness of the active and etch stop sub-layers may vary according to their position in the stack, just like the Si/Ge ratio forming the etch stop sub-layer.

This epitaxy step S130 is carried out in an epitaxy equipment, and consists in growing in an oriented manner, from the free surface 11 of the donor substrate 10 implanted with the first ions, a crystal corresponding to the crystal desired for the semiconductor monocrystalline layer 40. The epitaxy step may comprise forming a so-called nucleation crystalline sub-layer (not represented), on the free surface 11. The semiconductor layer 40 is then epitaxially grown following this sub-layer. The semiconductor layer 40 can be formed by Chemical Vapour Deposition (CVD) techniques such as Reduced Pressure-Chemical Vapour Deposition (RP-CVD) or Plasma-Enhanced Chemical Vapour Deposition (PECVD). Techniques such as Molecular-Beam Epitaxy (MBE) can also be used. In RP-CVD, for depositing Si or SiGe layers at low temperatures (500° C. and below), the operating points described in Hartmann et al, “Potentialities of disilane for the low temperature epitaxy of intrinsic and boron-doped SiGe”, Thin Solid Films 557, 19 (2014), Aubin et al, “Epitaxial growth of Si and SiGe at temperatures lower than 500° C. with disilane and germane”, Thin Solid Films 602, 36 (2016) or Hartmann et al, “A benchmark of germane and digermane for the low temperature growth of intrinsic and heavily in-situ boron-doped SiGe”, ECS Transactions 75 (8), 281 (2016), may be used.

To deposit pure Ge layers at temperatures less than or equal to 500° C., epitaxy conditions similar to those described in Aubin et al, “Very low temperature epitaxy of Ge and Ge rich SiGe alloys with Ge2H₆ in a Reduced Pressure—Chemical Vapour Deposition tool”, Journal of Crystal Growth 445, 65 (2016) could be used.

Finally, growth conditions for epitaxially growing GeSn or SiGeSn layers at temperatures less than or equal to 350° C. can be found in Aubin and Hartmann, “GeSn growth kinetics in reduced pressure chemical vapor deposition from Ge2H6 and SnCl4”, Journal of Crystal Growth 482, 30 (2018) and Khazaka et al, “Growth and characterization of SiGeSn pseudomorphic layers on 200 mm Ge virtual substrates,” Semiconductor Science and Technology 33, 124011 (2018).

These techniques involve applying a temperature Tₑₚ, referred to as the epitaxy temperature Tₑₚ, which may vary between 300° C. and 600° C. for a duration dₑₚ, referred to as the epitaxy duration dₑₚ, which may range from 1 min to 120 min. The epitaxy temperature Tₑₚ is, for example, 500° C. and the epitaxy duration dₑₚ is 10 minutes.

It should be noted that the temperatures involved in this epitaxy step S130 can produce the same effects as fracturing annealing on the first ions 3a implanted. For this reason, the first implantation (and especially the first ions 3a implanted and the first implantation dose(s) selected) is determined as a function of the temperature and duration conditions of the epitaxy step S130, to avoid (and not to obtain) fracturing of the donor substrate 10 during the epitaxy step S130. Indeed, in the opposite case, in the absence of any particular mechanical stress (or stiffener) in the donor substrate 10 (which has not yet been assembled to the receiver substrate 20), the gas-supplied nano-cavities are free to extend both laterally and vertically, which causes the appearance of bubbles, blisters and exfoliations on the surface and in the semiconductor layer 40 being formed, which will therefore be defective.

For this, light ions that do not generate bubbles with the thermal budget of epitaxy S130 can be selected as the first ions 3a. This will be the case, for example, if boron or helium is implanted. The heavier the implanted atom (He, B), the more advantageous it is to implant it before epitaxy S130 in order to limit damage to the semiconductor layer 40 transferred.

Preferably, the first light ions 3a are helium ions.

If the first implantation S120 is carried out with hydrogen, a first dose D1 is used that is lower than a first threshold S1 above which the first light ions 3a induce fracturing at the predetermined implantation depth 30 during epitaxy S130.

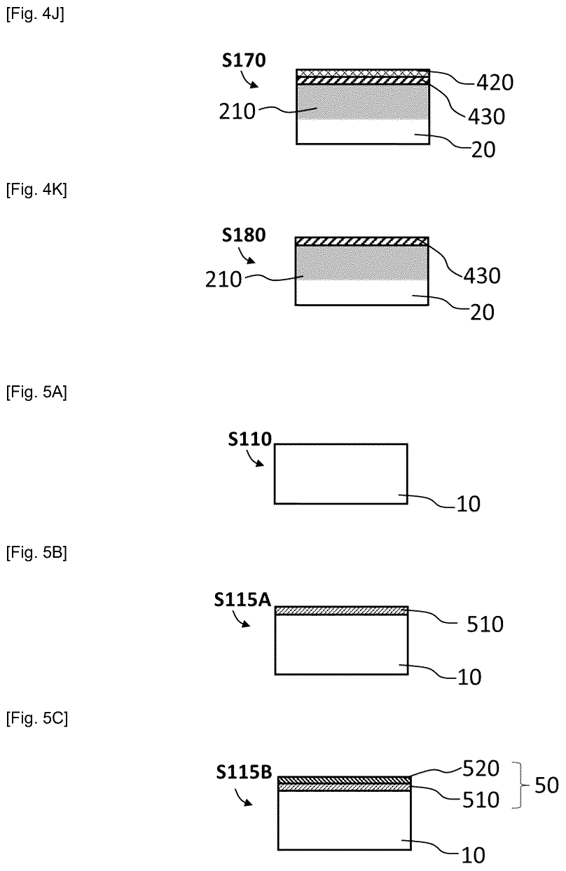

The first threshold S1 can be experimentally predetermined using a first test substrate 6 as represented in FIG. 6. The first test substrate 6 comprises several test zones, for example four test zones Q11, Q12, Q13 and Q14. Each test zone is subjected to implantation of the first ions with a test dose, and to a heat treatment at the temperature Tₑₚ of epitaxy S130, for the duration dₑₚ of epitaxy.

The first threshold S1 is then determined by visual inspection and by looking for the presence of surface exfoliations which indicate that fracturing and therefore layer transfer would take place if a mechanically stressing interface (such as the interface between the donor substrate 10 and the receiver substrate 20 when these are assembled) were present.

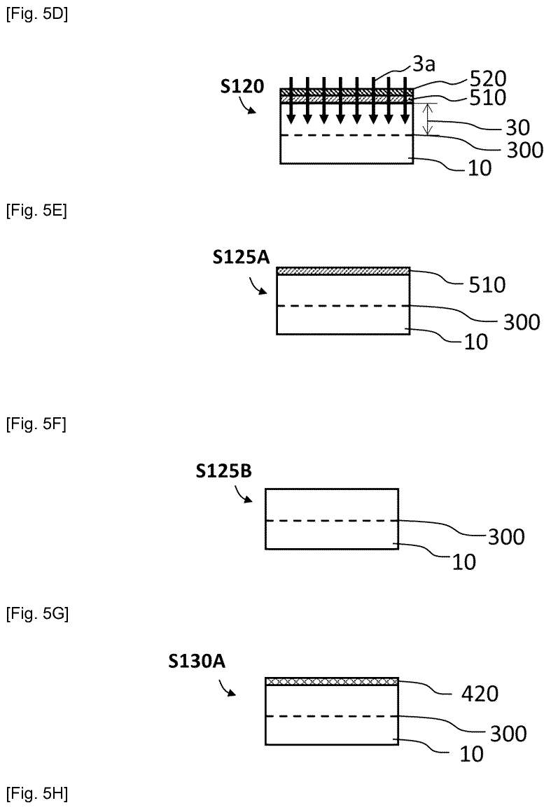

Preferably, the first threshold S1 is determined by following the sequence of steps S710 to S730 of FIG. 7.

These steps are as follows:
implanting S710 the first light ions 3a onto a first test zone Q11 of the test substrate 6, at the implantation energy of the first light ions 3a, and with a low first test dose DT1₁, for example 1^{e}16/cm².
heat treating S720 the test substrate 6 at the epitaxy temperature Tₑₚ for the epitaxy duration dₑₚ,
inspecting S730 the free surface 66 of the test substrate 6, preferably visually inspecting images of the test zone acquired by optical microscopy,
   If the free surface 66 is deteriorated (output “D” of step S730), the first threshold S1 is equal to the first test dose DT1₍₁)
   If the free surface is not deteriorated (output “ND” of step S730), the first test dose DT1₂ is increased (DT1₂>DT1₁) and the implantation step S710, heat treatment step S720 and inspection step S730 are repeated on the next test zone Q12, by applying the increased test dose D1₂ to the implantation step S710.

By “deteriorated free surface”, it is meant the presence of blisters or exfoliation on the free surface 66. This damage corresponds to dark spots on the optical microscopy images and is easily detected (see spots P in the image IMG1 in FIG. 7).

By “non deteriorated free surface 66”, it is meant the absence of blisters or exfoliation on the free surface 66. No dark spots are detected in the images acquired by optical microscopy (see IMG2 in FIG. 7).

For this first implantation S120, it will also be possible to combine several ions 3a, especially helium and/or boron with hydrogen. The more species implanted during this first implantation, the fewer will be required during the second implantation and therefore the less damaged the epitaxially grown layer.

After the epitaxy step S130 described previously, a second step of implanting light ions, referred to as the second step S140 of implanting light ions 3b, is performed. This step S140 is illustrated in FIG. 1D and is associated with the subsequent step S160, illustrated in FIG. 1E, consisting in a fracturing annealing step S150 performed at a fracturing annealing temperature T_{RF} and for a fracturing annealing duration d_{RF}.

The second ions 3b are light species such as helium He, hydrogen H or a mixture of helium and hydrogen (“H+He”). The second ions 3b may be the same as the first ions 3a.

Preferably, the second light ions 3b comprise or are hydrogen ions.

The depth of this second implantation S140 is the implantation depth 30 determined during the first implantation S120 of the first ions 3a, to which is added the thickness of the semiconductor layer 40 epitaxially grown. The energy at which the second implantation S140 is carried out is such that the maximum of the implantation profile is superimposed on that of the first implantation S120.

With reference to FIG. 1D, the second implantation S140 is performed in the donor substrate 10, through the semiconductor layer 40 to be transferred, so that the second ions 3b reach the buried brittle plane 300.

The brittle plane 300 is then a plane in which the density of nano-cavities and the overall content of light ions, that is, the cumulative content of first light ions 3a and second light ions 3b, make it possible, during the fracturing annealing step S160, to trigger the formation of gaseous complexes leading to fracturing of the donor substrate 10.

For this, the second implantation S140 is carried out with ions 3b implanted at one or more doses such that, during fracturing annealing S160, the accumulation of the first ions 3a and the second ions 3b induces fracturing of the donor substrate 10, in the buried brittle plane 300.

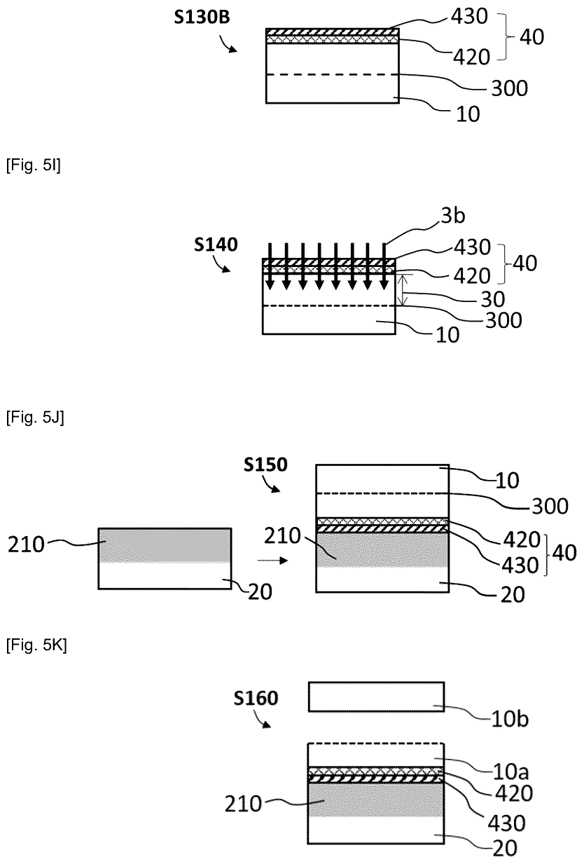

If the second implantation S140 comprises hydrogen ions implanted at a second dose D2, this dose is preferably experimentally predetermined, based, in a similar way to determining the first threshold S1, on the presence/absence of exfoliations on the surface of a second test substrate such as the second test substrate 8 illustrated in FIG. 8.

In a similar way to the first test substrate 6, the second test substrate 8 can be divided into several test zones, for example four zones Q21, Q22, Q23 and Q24.

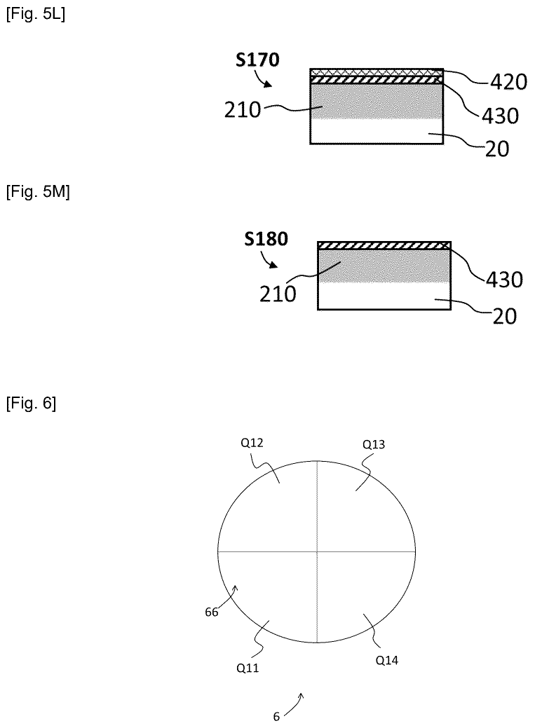

Steps S910 to S950 (see FIG. 9) are carried out therein. They consist in:
implanting S910 the first ions 3a onto a first zone Q21, at the implantation energy of the first ions. For example, Helium ions are implanted with an energy of 35 keV (so as to create a brittle plane at a depth of 300 nm relative to the surface) and a dose D1 of 2^{e}16/cm²),
epitaxially growing S920 the second test substrate 8 at the epitaxy temperature Tₑₚ and for the epitaxy duration dₑₚ, to create a layer epitaxially grown of, for example, 30 nm
implanting S930 the second ions 3b with an implantation energy such that these ions reach the buried brittle plane. If the implanted ions are hydrogen, they will be implanted with an energy of 24 keV to reach the brittle plane located 330 nm from the surface. These ions will be implanted with a second low test dose DT21, for example equal to 1E16/cm²,
heat treating S940 the second test substrate 8 at the fracturing annealing temperature T_{RF} and for the fracturing annealing duration d_{RF},
inspecting S950 the quality of the free surface 88 of the second test substrate 8,
   if the surface quality is deteriorated (output “D” of the inspection step S950), the second dose D2 is equal to or greater than the second test dose DT21,
   if the surface quality is not deteriorated (output “ND” of the inspection step S950), the test dose DT21 is increased and the test steps S910 to S930 are repeated on another test zone Q22, the step S930 of implanting the second ions 3b being carried out with the increased second test dose DT22.

By applying these steps, for example, the fracturing conditions given in Table 1 or the fracturing conditions given in Table 2 are obtained. By “fracturing conditions”, it is meant the set of parameters related to the implantation S120 of the first ions, epitaxy S130, implantation S140 of the second ions, and fracturing annealing S160.

TABLE 1

| | Implantation of | Epitaxy | Implantation of the | |
|---|---|---|---|---|
| | the first light ions | S130 30 | second light ions | Fracturing |
| | S120 | nm Si | S140 | annealing S160 |
| Light ions | He | | H | |
| Energy | 36 | | 2 | |
| (keV) | | | | |
| Dose (/cm²) | 1.3^{e}16 | | 1^{e}16 | |
| Temperature | | 400 | | 500 |
| (° C.) | | | | |
| Duration | | 15 | | 1 h |
| (min) | | | | |

TABLE 2

| | Implantation of | Epitaxy | Implantation of the | |
|---|---|---|---|---|
| | the first light ions | S130 30 | second light ions | Fracturing |
| | S120 | nm Si | S140 | annealing S160 |
| Light ions | He | | H | |
| Energy | 36 | | 24 | |
| (keV) | | | | |
| Dose (/cm²) | 2^{e}16 | | 2^{e}16 | |
| Temperature | | 500 | | 500 |
| (° C.) | | | | |
| Duration | | 15 | | 1 h |
| (min) | | | | |

It should be noted that using a higher epitaxy temperature Tₑₚ (500° C., see Table 2, compared to 400° C., see Table 1) leads to a larger first dose D1 (2^{e}16/cm² compared to 1.3^{e}16/cm²) and a larger second dose D2 (2^{e}16/cm² compared to 9^{e}15/cm²).

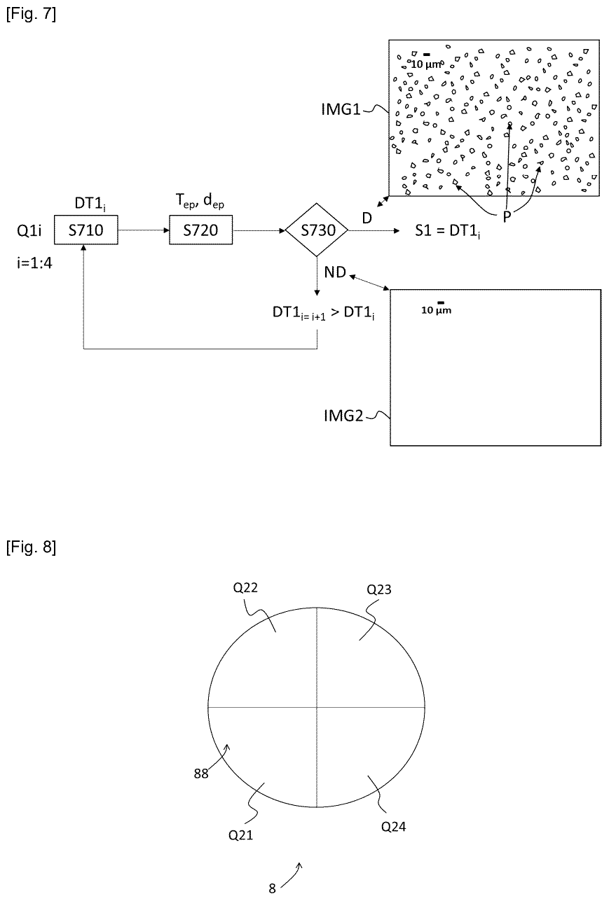

It should be also noted that, in this case, the overall dose (He 36 keV 2^{e}16/cm² and H 24 keV 2^{e}16/cm²) is greater than the dose applied in the standard way in the case of a single light ion implantation. However, fewer defects are created, especially as the helium ions do not pass through the semiconductor layer 40 transferred. As illustrated in FIG. 10, the density of displaced atoms is indeed lower when hydrogen ions are implanted, compared to helium ions, even for an implantation dose of hydrogen ions greater than twice the implantation dose of helium ions.

With reference to FIG. 1E, the method then comprises a step S150 of assembling by bonding the receiver substrate 20 and the donor substrate 10 covered with the semiconductor layer 40 to be transferred. The donor substrate 10 having been previously turned over, the semiconductor layer 40 to be transferred is disposed between the receiver 20 and the donor 10 substrates, in the assembly 1 formed.

The receiver substrate 20 is a substrate preferably comprising one or more layers of electronic devices 210.

This assembly step S150 is performed using a conventional bonding method, preferably a molecular adhesion assembling method, also referred to as direct bonding.

The assembly step S150 is followed by a step S160 of fracturing by annealing, also referred to as the step S160 of fracturing annealing, the donor substrate 10 in the buried brittle plane 300. The temperature of fracturing annealing is in a range between 400° C. and 600° C., and preferably less than or equal to 500° C. The duration of fracturing annealing is preferably between 30 minutes and 180 minutes.

At the end of this step S160 of fracturing by annealing, a portion 10b of the donor substrate 10 is separated from the receiver substrate 20 onto which the transferred semiconductor layer 40 is disposed, as well as a residual layer 10a originating from the donor substrate 10. Transfer of the semiconductor layer 40 is thus carried out.

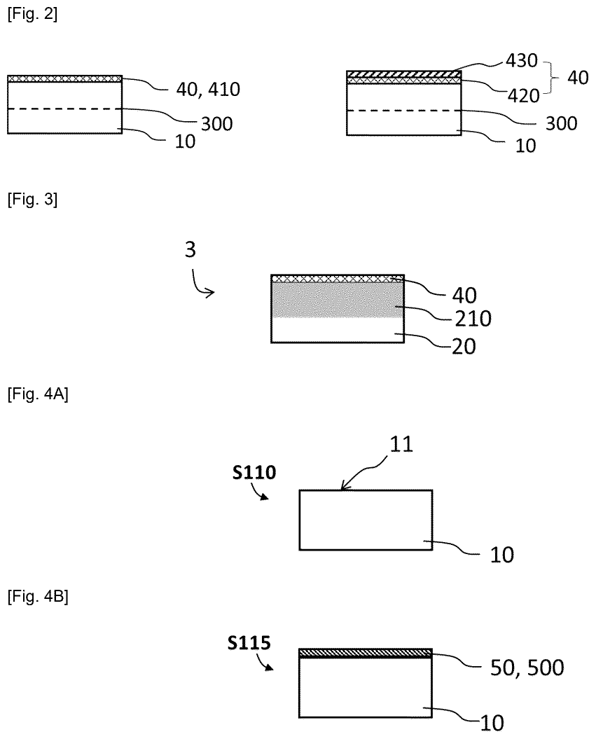

With reference to FIG. 1G, the fracturing step S160 may be followed by an optional step S170 of removing the residual layer 10a originating from the donor substrate 10 until the semiconductor layer 40 is reached. At the end of this step S170 of removing the residual layer 10a, the final semiconductor structure 3, illustrated in FIG. 3, is obtained.

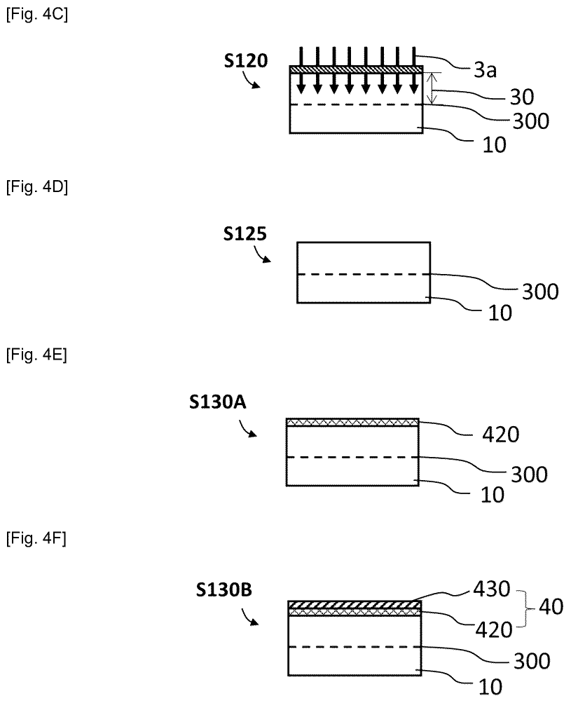

FIGS. 4A to 4K schematically represent a first particular embodiment of the transfer method just described in general terms.

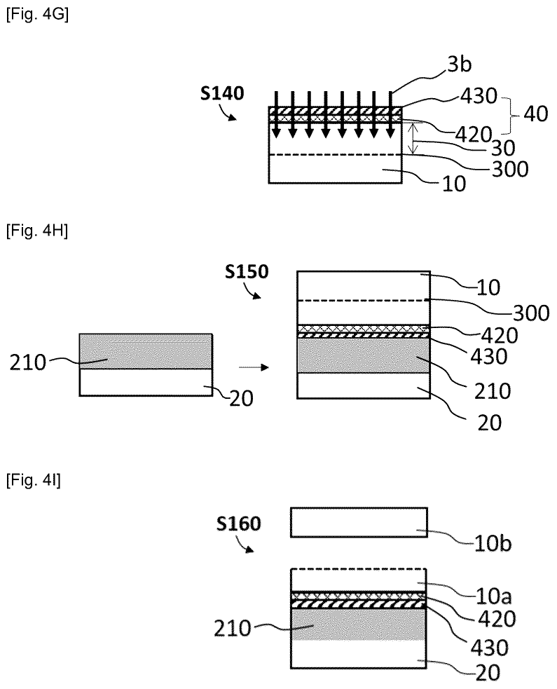

FIGS. 5A to 5M schematically represent a second particular embodiment of the transfer method.

The steps of providing S110 the donor substrate 10, of first implantation S120, and of second implantation S140, illustrated in FIG. 4A and FIG. 5A, in FIG. 4C and FIG. 5D, and in FIG. 4G and FIG. 5I, respectively, are such as previously described, in connection with FIG. 1A, FIG. 1B, and FIG. 1D, respectively.

Common to these two particular embodiments, the epitaxy step S130 comprises two sub-steps S130A and S130B to form a semiconductor layer 40 comprising the active sub-layer 430 and the etch stop sub-layer 420 illustrated in FIG. 2, as well as two additional steps S170 (see FIG. 4J and FIG. 5L) and S180 (see FIG. 4K and FIG. 5M) carried out after the assembly step S150 (see FIG. 4H and FIG. 5J) and the fracturing step S160 (see FIG. 4I and FIG. 5K) and aiming at releasing the active sub-layer 430.

With reference to FIG. 4E (first embodiment) and FIG. 5G (second embodiment), step S130A consists in epitaxially growing the so-called etch stop sub-layer 420 from the free surface 11 of the donor substrate 10. The epitaxy temperature is 500° C., for example.

With reference to FIG. 4F (first embodiment) and FIG. 5H (second embodiment), step S130B consists in epitaxially growing the so-called active sub-layer 430 from the etch stop sub-layer 420. This epitaxy S130B is preferably performed at the same epitaxy temperature as the epitaxy S130A of the etch stop sub-layer, herein 500° C.

With reference to FIG. 4J (first embodiment) and FIG. 5L (second embodiment), the receiver substrate 20 has, after the fracturing step S160, a residual layer 10a originating from the donor substrate 10 on the surface of the etch stop sub-layer 420. Step S170 is then a step of removing S170 the residual layer 10a originating from the donor substrate 10, by selectively etching said residual layer 10a relative to the second etch stop sub-layer 420. This selective etching is preferably wet etching.

Step S180, which follows step S170, is a step of removing the etch stop sub-layer 420 from the active sub-layer 430 by selective (preferably wet) etching.

At the end of step S180 of removing the etch stop sub-layer 430, the active sub-layer 430 is released and advantageously has a smooth surface and reduced thickness.

Also common to the first embodiment and the second embodiment, the transfer method further comprises one or more steps aiming at preparing the free surface 11 of the donor substrate 10 for epitaxy S130 of the semiconductor layer 40.

In the first embodiment, preparation of the surface for epitaxy S130 comprises the additional steps S115 and S125 illustrated in FIG. 4B and FIG. 4D, respectively.

In the second embodiment, preparation of the surface for epitaxy S130 comprises the additional steps S115A, S115B and S125A and S125B, illustrated in FIG. 5B, FIG. 5C and FIG. 5E and FIG. 5F, respectively.

Surface preparation as carried out in the first embodiment is described first hereinafter.

Step S115 (FIG. 4B) takes place before implanting S120 the first ions 3a, and consists in forming a sacrificial layer 50 on the free surface 11 of the donor substrate 10. Preferably, the sacrificial layer 50 is a dielectric layer 500, for example a layer of silicon oxide (or SiO₂).

The dielectric layer 500 is obtained by oxide growth or by deposition of the dielectric from the free surface 11 of the donor substrate 10.

At the end of step S115, the donor substrate 10 therefore comprises a so-called dielectric sacrificial layer which advantageously protects the free surface from defects and impurities (for example carbon or oxygen atoms). In the step S120 of implanting the first ions 3a, the first ions 3a are implanted through the sacrificial dielectric layer 50, 520.

Step S125 (FIG. 4D) takes place after implanting S120 the first ions and before the step S130 of epitaxially growing the semiconductor layer 40 to be transferred. Step S125 consists in removing the sacrificial layer 50,510 formed in step S115.

This removal is carried out, for example, by wet etching using a hydrofluoric acid-based solution.

At the end of step S125, the free surface 11 of the donor substrate 10 advantageously has a clean surface, that is, devoid of impurities or contaminants.

In the second embodiment (see FIG. 4C), the sacrificial layer 50 comprises a stack of a first sub-layer 510, referred to as the first etch stop layer 510, and a second dielectric sub-layer 520 disposed onto the first sub-layer 510.

Thus, step S115A is a step of forming the first etch stop layer 510 and step S115B is a step of forming the second dielectric sub-layer 520.

The dielectric is preferably silicon oxide.

The first etch stop layer 510 is for example a layer of silicon/germanium (SiGe) alloy with the following proportions 25% (Si) and 50% (Ge).

In step S115A, forming the first etch stop layer 510 is preferably carried out by epitaxial growth from the free surface 11 of the donor substrate 10. The thickness of the first etch stop layer 510 thus obtained is between 10 and 50 nm. Epitaxy of the first etch stop layer 510 may furthermore follow a surface preparation step carried out according to methods in the state of the art, preferably at temperatures greater than 650° C. and still preferably at temperatures greater than 850° C.

In step S115B, the second dielectric sub-layer 520 is obtained by oxide growth from the surface of the first etch stop layer 510, or by deposition of the dielectric onto the surface of the first etch stop layer 510, to obtain a second dielectric sub-layer 520 with a thickness of between 5 and 50 nm.

The removal step S125A (FIG. 5E) is a step of removing S125A the second dielectric sub-layer 520.

Removing the second dielectric sub-layer 520 is carried out, for example, using wet etching based on a solution comprising hydrogen fluoride.

The step S125B (FIG. 5F) of removing the first etch stop layer 510 can be carried out outside the epitaxy equipment or in the epitaxy equipment (this is referred to as in-situ removal).

In the first case (outside the epitaxy equipment), step S125B consists in performing selective wet etching with respect to SiGe, for example using wet etching based on a solution comprising acetic acid, hydrogen fluoride and hydrogen peroxide (or H2O2), and then performing the epitaxy step S130 in a time interval preferably of between 10 minutes and 30 minutes.

Stated differently, the time interval between the step of removing S125B by wet etching the first etch stop layer 510 and the step S130 of epitaxially growing the semiconductor layer 40 to be transferred is then preferably between 10 minutes and 30 minutes.

In the second case, the step S125B of removing the first etch stop layer 510 is carried out in the epitaxy equipment. Stated differently, the step S125B of removing the first etch stop layer 510 and the epitaxy step S130 are carried out in the same epitaxy equipment.

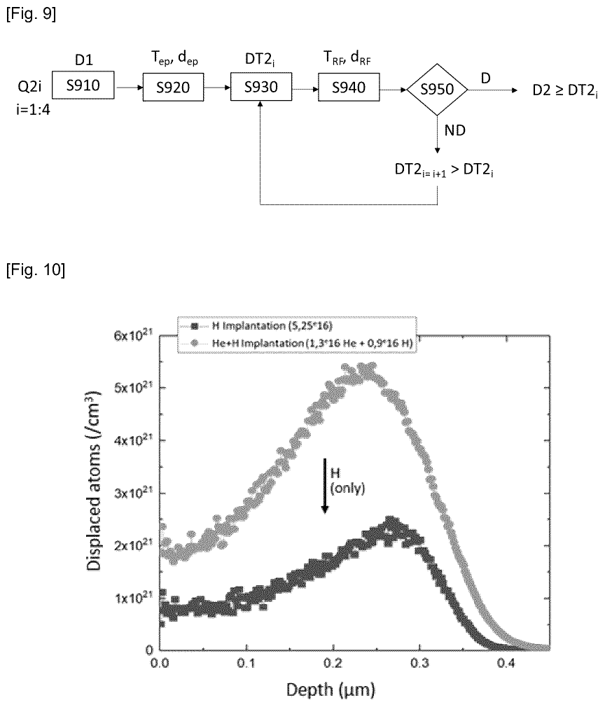

Removal S125B is then performed by wet etching using a solution comprising hydrochloric acid (or HCl) at a temperature preferably less than 500° C. Advantageously, etching is selective with respect to the silicon of the donor substrate 10. With reference to FIG. 11, a partial pressure of HCl of 23998 Pa to 47996 Pa (that is, 180 or 360 Torr) can be used. At a temperature of 500° C., the Etching rates (ER), represented on the axis y, are such that etching of the SiGe is selective relative to the silicon of the donor substrate 10. Advantageously, etching selectivity, that is, the ratio between the etching rate of a SiGe layer and that of Si, is in the order of 13 for a Ge concentration in the etch stop layer 510 of 20%, in the order of 50 for a Ge concentration of 30% and in the order of 186 for a Ge concentration of 40%.

Removal S125B is then followed by the epitaxy step S130 described previously, which may then, furthermore, be followed by an additional step S132 (not represented) of annealing, after epitaxy, the donor substrate 10, carried out in the same epitaxy equipment as the step of removing S125B the first stop layer 510 and the step S130 of epitaxially growing the semiconductor layer 40 to be transferred.

The first and second embodiments represent two ways of preparing the free surface 11 of the donor substrate 10 for epitaxy S130.

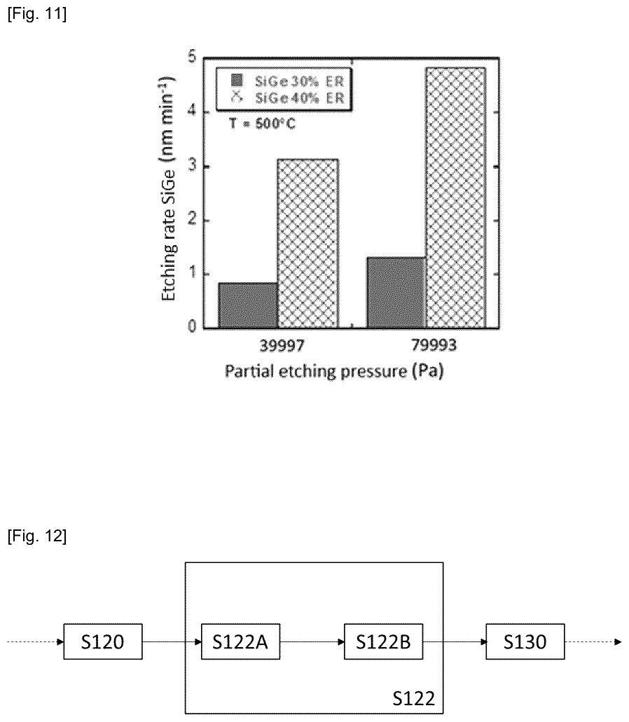

A third way of preparing the free surface 11 is represented in FIG. 12 with step S122. This step S122 consists in carrying out, between the implantation S120 of the first light ions and the step S130 of epitaxially growing the semiconductor layer 40 to be transferred, the following successive sub-steps of:
deoxidising S122A the free surface 11 of the donor substrate 10,
annealing S122B the donor substrate 10, in an atmosphere comprising hydrogen at a temperature greater than 400° C., for a duration of between 5 seconds and 10 minutes, typically.

The deoxidation step S122A is for example carried out chemically, under hydrogen fluoride (or HF), and is followed by surface cleaning by an SC1™ method (that is, exposure of the surface to a chemical solution NH₄OH:H₂O₂:H₂O, leading to the formation of a silicon oxide) and then a SICONI™ method (that is, (i) converting, by virtue of an NH₍₃₎- and NF₃-based remote plasma, the silicon oxide formed as a result of the SC1™ method into an oxide salt, followed by subliming this salt under neutral gas at a temperature less than 200° C.). The temperatures used are preferably less than or equal to 500° C.

The annealing step S122B, which follows the deoxidation step S122A, is preferably carried out in the epitaxy equipment. The annealing temperature may be less than 500° C. To obtain optimum surface preparation, the temperature may be higher, for example the temperature may be greater than 500° C., 650° C. or even greater than 800° C. In this case, the annealing duration is preferably as short as possible, in a range from 5 seconds to 10 minutes.

At the end of this additional step S122, the free surface 11 of the donor substrate 10 advantageously has reduced contaminants (carbon, fluorine, oxygen, etc.) before epitaxy S130.

The method may further comprise, after epitaxy S130 and before implantation S140 of the second ions 3b, an additional step S135 (not represented) of forming an oxide layer carried out by epitaxial growth from the semiconductor layer 40 formed at the end of step S130 (or S130B). This step S135 is preferably carried out under oxidation plasma at a temperature less than 500° C. or less than 400° C. It can also be carried out by plasma-assisted chemical vapour deposition.

By using two implantation steps (first implantation S120 and second implantation S140) carried out respectively with the first ions 3a and the first dose(s) and with the second ions 3b and the second dose(s), and by interposing epitaxy of the semiconductor layer 40 between these two implantation steps, the transfer method makes it possible to limit the negative impact of implantation, that is, to limit the damage or defects induced by the species implanted along their path in the donor substrate 10. The method therefore makes it possible to obtain a semiconductor layer 40 having reduced defects, before the transfer step S150-S160.

There are several explanations for this: firstly, the first ions 3a and the first dose(s) are adapted so that, during epitaxy, the first ions 3a do not induce the growth of nano-cavities towards the free surface 11 and in the semiconductor layer 40 being formed; secondly, the semiconductor layer 40 only has the second ions 3b passing therethrough, at a second, reduced dose compared to a dose corresponding to a single implantation.

Fracturing annealing temperatures less than or equal to 500° C. can be used, as previously described, making the transfer method compatible with 3D monolithic integration.

1. A method for transferring a semiconductor layer from a donor substrate to a receiver substrate, the method comprising the following successive steps of:
firstly implanting first light ions into the donor substrate at a predetermined implantation depth so as to form a buried brittle plane at the predetermined implantation depth
epitaxially growing, on the donor substrate, the semiconductor layer to be transferred,
secondly implanting second light ions into the donor substrate through the semiconductor layer to be transferred at the brittle plane,
assembling by bonding the receiver substrate and the donor substrate covered with the semiconductor layer to be transferred, the semiconductor layer to be transferred being disposed between the receiver and donor substrates, and
fracturing by annealing, referred to as fracturing annealing, the donor substrate in the buried brittle plane
wherein:
the first ions are selected and implanted at a first dose so that, during epitaxy, there is no fracturing at the predetermined implantation depth,
the second ions are selected and implanted at a second dose so that, during fracturing annealing, fracturing of the donor substrate takes place.

2. The method according to claim 1, wherein:
the first light ions are helium ions, hydrogen ions, boron ions, a mixture of helium ions and hydrogen ions or a mixture of hydrogen ions and boron ions, and
the second light ions are helium ions, hydrogen ions or a mixture of helium ions and hydrogen ions.

3. The method according to claim 1, comprising, between the first implantation and the step of epitaxially growing the semiconductor layer to be transferred, an additional surface preparation step comprising the following successive sub-steps of:
deoxidising a free surface of the donor substrate,
annealing the donor substrate in an atmosphere comprising hydrogen at a temperature greater than or equal to 400° C., for a duration of between 5 seconds and 10 minutes.

4. The method according to claim 1, comprising the additional steps of:
before the first implantation, a step of depositing a sacrificial layer onto a free surface of the donor substrate,
after the first implantation and before the step of epitaxially growing the semiconductor layer to be transferred, a step of removing the sacrificial layer.

5. The method according to claim 4, wherein the sacrificial layer is a dielectric layer.

6. The method according to claim 4, wherein the sacrificial layer comprises a stack of a first sub-layer of silicon/germanium alloy, referred to as a first etch stop layer, and a second sub-layer of dielectric material disposed onto the first sub-layer, and the step of removing the sacrificial layer comprises removing the second sub-layer of dielectric material and then removing the first etch stop layer.

7. The method according to claim 6, wherein the step of epitaxially growing the semiconductor layer to be transferred is carried out less than 30 minutes after the step of removing the first stop layer.

8. The method according to claim 6, wherein the step of removing the first etch stop layer and the step of epitaxially growing the semiconductor layer to be transferred are carried out in a same equipment.

9. The method according to claim 8, comprising, after the step of removing the first stop layer and before the step of epitaxially growing the semiconductor layer to be transferred, an additional step of annealing the donor substrate carried out in the same equipment as the step of removing the first etch stop layer and the step of epitaxially growing the semiconductor layer to be transferred.

10. The method according to claim 9, wherein annealing the donor substrate is carried out under the following temperature, pressure and duration conditions: 500° C., 2666 Pa, 2 minutes.

11. The method according to claim 1, wherein the semiconductor layer to be transferred is a layer of silicon, germanium, a silicon/germanium alloy, a silicon/germanium/carbon alloy, a germanium/tin alloy or a silicon/germanium/tin alloy, or a stack of a sub-layer of silicon and a sub-layer of silicon/germanium alloy.

12. The method according to claim 1, wherein the semiconductor layer to be transferred comprises a first so-called active sub-layer of silicon, germanium, a silicon/germanium alloy, a silicon/germanium/carbon alloy, a germanium/tin alloy or a silicon/germanium/tin alloy, and a second so-called etch stop sub-layer, such as an etch stop sub-layer of silicon/germanium alloy, disposed under the first active sub-layer, and the receiver substrate has, after the fracturing step, a residual layer originating from the donor substrate, the method then comprising the following successive steps of:
Removing the residual layer originating from the donor substrate by selectively etching said residual layer relative to the second etch stop sub-layer, with a selectivity greater than 10,
Removing the second etch stop sub-layer.
